(19) United States
(12) Patent Application Publication
(10) Pub. No.: US 2025/0311345 A1
(43) Pub. Date: Oct. 2, 2025

(54) SILICON CARBIDE MOSFET STRUCTURE AND PREPARATION METHOD THEREOF

(71) Applicant: SUCCESS TECHNOLOGY LIMITED, Hong Kong (CN)

(72) Inventors: CHEN-YEN LEE, Hong Kong (CN); CHUNG YAO NI, Hong Kong (CN)

(21) Appl. No.: 18/895,412

(22) Filed: Sep. 25, 2024

(30) Foreign Application Priority Data
Apr. 2, 2024 (CN) 202410396874.7

(51) Int. Cl. H01L 29/16; H01L 29/66

(52) U.S. Cl. CPC H10D 62/8325; H10D 12/031

(57) ABSTRACT

A preparation method of a silicon carbide MOSFET structure is provided, and the preparation method includes: generating an epitaxial layer, which includes a first surface and a second surface; generating a first body area, a second body area and a reinforcing layer on the epitaxial layer, where the first body area and the second body area extend along a second direction crossing a first direction, the reinforcing layer is disposed between the first body area and the second body area, and extends along the first direction; forming a first source area on the first body area, and forming a second source area on the second body area, where the first source area and the second source area extend along the second direction; and forming an oxide layer on the second surface, which extends along the second direction. In addition, a silicon carbide MOSFET structure is also provided.

### CROSS-REFERENCE TO RELATED APPLICATION

This application claims priority to Chinese Patent Application No. 202410396874.7, filed on Apr. 2, 2024, which is herein incorporated by reference in its entirety.

### TECHNICAL FIELD

The disclosure relates to the field of semiconductor technologies, and more particularly to a silicon carbide metal-oxide-semiconductor field effect transistor (MOSFET) structure and a preparation method thereof.

### BACKGROUND

Metal-oxide-semiconductor (MOS) structure is an electronic device structure based on semiconductor materials, and consists of a metal electrode, an oxide layer, a semiconductor and the like. The MOS structure has a wide range of application scenarios, including but not limited to the following fields: integrated circuits, such as: a logic gate, a memory and an amplifier; high frequency electronic devices, such as: a radio frequency (RF) amplifier and a signal mixer; and power management, such as: a direct current to direct current (DC-DC) converter and a power inverter. Features of the MOS structure includes high input impedance, low power consumption, large dynamic range, and strong integration capability. In an MOS structure device, a breakdown electric field of a silicon carbide MOS structure can be several times that of a silicon MOS structure, thus achieving high voltage resistance with low impedance and thin thickness. Nevertheless, continuous improvement of reliability of a silicon carbide MOS device remains an important research and technological development direction for those skilled in the art.

### SUMMARY

In order to solve a technical problem of improving reliability of a silicon carbide MOSFET structure, the disclosure provides a silicon carbide MOSFET structure and a preparation method thereof. The silicon carbide MOSFET structure achieves a technical effect of improving the reliability of the silicon carbide MOSFET structure through a technical mean of setting a reinforcing layer.

In a first aspect, embodiments of the disclosure provides a preparation method of a silicon carbide MOSFET structure, and the preparation method includes:
generating an epitaxial layer; where the epitaxial layer includes a first surface and a second surface;
generating a first body area, a second body area and a reinforcing layer on the epitaxial layer; where the first body area and the second body area are disposed on a side of the epitaxial layer proximate to the second surface, the first body area and the second body area are opposite in a first direction and are arranged at intervals, and the first body area and the second body area extend along a second direction crossing the first direction; and the reinforcing layer is disposed between the first body area and the second body area, and extends along the first direction, and the reinforcing layer is in contact with the first body area, the second body area and the epitaxial layer;
forming a first source area on the first body area, and forming a second source area on the second body area; where the first source area is disposed on a side of the first body area proximate to the second surface, the second source area is disposed on a side of the second body area proximate to the second surface, and the first source area and the second source area extend along the second direction; and
forming an oxide layer on the second surface; where the oxide layer extends along the second direction, and the oxide layer is connected to the epitaxial layer, the first body area, the second body area, the first source area, the second source area and the reinforcing layer; and
where doping concentrations of the first body area, the second body area and the reinforcing layer are the same; and a doping type of each of the first body area, the second body area and the reinforcing layer is a first doping type, and a doping type of each of the first source area, the second source area and the epitaxial layer is a second doping type.

In an embodiment of the disclosure, the reinforcing layer is multiple in number, and the generating a first body area, a second body area and a reinforcing layer on the epitaxial layer, includes:
forming the multiple reinforcing layers between the first body area and the second body area; where the multiple reinforcing layers are arranged in the second direction and arranged at intervals.

In an embodiment of the disclosure, the preparation method further includes:
generating a buffer layer in the epitaxial layer; where the buffer layer is disposed between two adjacent reinforcing layers of the multiple reinforcing layers, a doping type of the buffer layer is the second doping type, and a doping concentration of the buffer layer is different from a doping concentration of the epitaxial layer.

In an embodiment of the disclosure, the doping concentration of the buffer layer is lower than a doping concentration of each of the first source area and the second source area, and the doping concentration of the epitaxial layer is lower than the doping concentration of the buffer layer.

In an embodiment of the disclosure, an interval range between the two adjacent reinforcing layers of the multiple reinforcing layers is 0.1-10 microns (μm).

In an embodiment of the disclosure, a number of impurity atoms per cubic centimeter in the buffer layer ranges from 10¹⁷-10¹⁸.

In an embodiment of the disclosure, a thickness of the buffer layer in a direction from the first surface to the second surface is the same as a thickness of the reinforcing layer in the direction from the first surface to the second surface.

In an embodiment of the disclosure, a thickness range of the buffer layer in the direction from the first surface to the second surface is 0.1-10 μm.

In another aspect, the embodiments of the disclosure provide a silicon carbide MOSFET structure, and the silicon carbide MOSFET structure is prepared by using any one of the preparation methods of the silicon carbide MOSFET structure described above.

Still another aspect, the embodiments of the disclosure provide a silicon carbide MOSFET structure, and the silicon carbide MOSFET structure includes: an epitaxial layer, a first body area, a second body area, a reinforcing layer, a first source area, a second source area and an oxide layer.

The epitaxial layer includes a first surface and a second surface opposite to each other. The first body area and the second body area are disposed in the epitaxial layer, and are disposed on a side of the epitaxial layer proximate to the second surface; and the first body area and the second body area are opposite in a first direction and are arranged at intervals, and extend along a second direction crossing the first direction. The reinforcing layer is disposed between the first body area and the second body area, and extends along the first direction, and the reinforcing layer is in contact with the first body area, the second body area and the epitaxial layer. The first source area is embedded in the first body area, and the second source area is embedded in the second body area. The first source area is located at a side of the first body area proximate to the second surface, and the second source area is located at a side of the second body area proximate to the second surface. The first source area and the second source area extend along the second direction. The oxide layer is located on the second surface and extends along the second direction, and the oxide layer is connected to the epitaxial layer, the first body area, the second body area, the first source area, the second source area and the reinforcing layer. Doping concentrations of the first body area, the second body area and the reinforcing layer are the same. A doping type of each of the first body area, the second body area and the reinforcing layer is a P-type, and a doping type of each of the first source area, the second source area and the epitaxial layer is an N-type.

As can be seen from the above, the above technical solutions has at least one beneficial effect as follows:

In the embodiments of the disclosure, the reinforcing layer is disposed between the first body area and the second body area, so that a partially conductive area of the epitaxial layer between the first body area and the second body area is reinforced without affecting the channel width. Moreover, electric field distribution is increased, so as to make the electric field more even. Meanwhile, an electric field intensity proximate to the channel is reduced, so as to decrease an effect of uneven electric field intensity on the silicon carbide MOSFET structure, reduce a risk of breakdown of the oxide layer, and improve the reliability of the silicon carbide MOSFET structure. Moreover, the doping concentrations and the doping types of the first body area, the second body area and the reinforcing layer are the same, which helps to ensure consistency and stability of the silicon carbide MOSFET structure, so that the reliability of the silicon carbide MOSFET structure is improved, and the stability of the silicon carbide MOSFET structure is improved.

### BRIEF DESCRIPTION OF DRAWINGS

In order to provide a clearer description of technical solutions in embodiments of the disclosure, drawings required in embodiment descriptions will be introduced below. Apparently, the following described drawings are merely some of the embodiments of the disclosure, for those skilled in the art, other drawings can be obtained according to these drawings without creative work.

FIG. 1 illustrates a schematic structural diagram of a silicon carbide MOSFET structure according to an embodiment of the disclosure.

FIG. 2 illustrates a three-dimensional structural diagram of the silicon carbide MOSFET structure according to an embodiment of the disclosure.

FIG. 3 illustrates a three-dimensional structural diagram of an epitaxial layer of the silicon carbide MOSFET structure shown in FIG. 2 according to an embodiment of the disclosure.

FIG. 4 illustrates a schematic top diagram of the epitaxial layer of the silicon carbide MOSFET structure in FIG. 3 according to an embodiment of the disclosure.

FIG. 5 illustrates another three-dimensional structural diagram of the epitaxial layer of the silicon carbide MOSFET structure shown in FIG. 2 according to an embodiment of the disclosure.

FIG. 6 illustrates a sectional diagram of the silicon carbide MOSFET structure along an A-A direction shown in FIG. 5 according to an embodiment of the disclosure.

FIG. 7 illustrates a sectional diagram of the silicon carbide MOSFET structure along a B-B direction shown in FIG. 5 according to an embodiment of the disclosure.

FIG. 8 illustrates a three-dimensional structural diagram of an epitaxial layer of another silicon carbide MOSFET structure according to an embodiment of the disclosure.

FIG. 9 illustrates a schematic top diagram of the epitaxial layer of another silicon carbide MOSFET structure of FIG. 8 according to an embodiment of the disclosure.

FIG. 10 illustrates a sectional diagram of the epitaxial layer of another silicon carbide MOSFET structure along a C-C direction shown in FIG. 9 according to an embodiment of the disclosure.

### DETAILED DESCRIPTION OF EMBODIMENTS

Technical solutions in embodiments of the disclosure are clearly and completely described in conjunction with drawings in the embodiments of the disclosure below. Apparently, the described embodiments are merely some of the embodiments of the disclosure, not all of them. Based on the embodiments of the disclosure, all other embodiments obtained by those skilled in the art without creative work fall within a scope of protection of the disclosure.

It should be noted that terms “first”, “second”, “an end” and the like in specification and claims of the disclosure are used to distinguish similar objectives, and do not need to be used to describe a specific order or sequence. It should be understood that the terms used in this way can be interchanged in appropriate cases, so that the embodiments of the disclosure described herein can be implemented in order other than those illustrated or described herein. In addition, terms “including” and “having”, as well as any variations thereof, are intended to cover non-exclusive inclusion, for example, a process, system, product, or device that includes a series of steps or units need not be limited to those clearly listed steps or units, but may include other steps or units that are not clearly listed or inherent to these processes, products, or device.

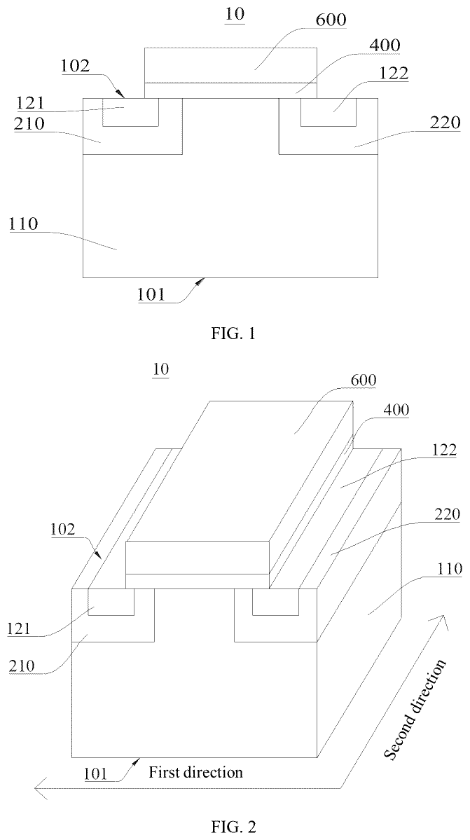

As shown in FIGS. 1-3, the embodiments of the disclosure provide a silicon carbide MOSFET structure 10. The silicon carbide MOSFET structure 10 includes an epitaxial layer 110, a first body area 210, a second body area 220, a first source area 121, a second source area 122, an oxide layer 400 and a reinforcing layer 230.

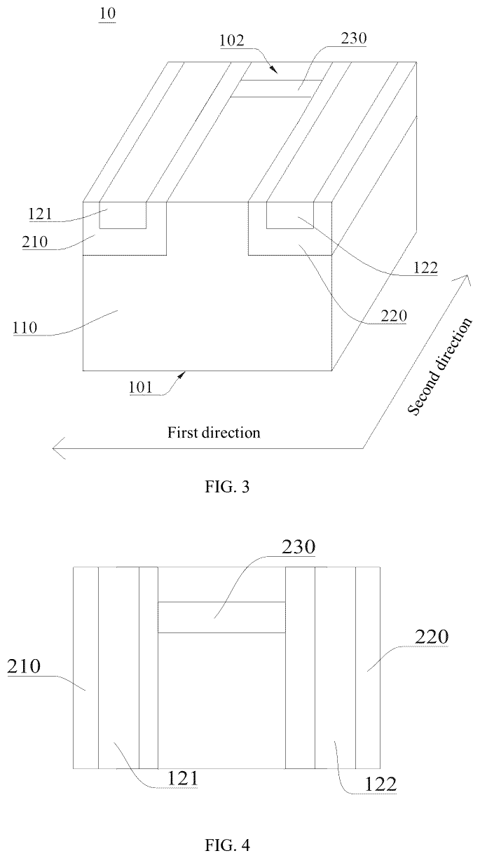

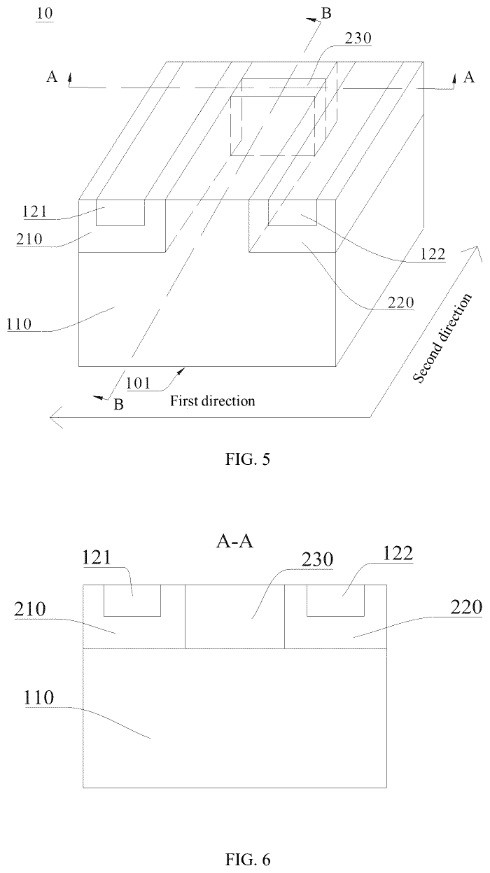

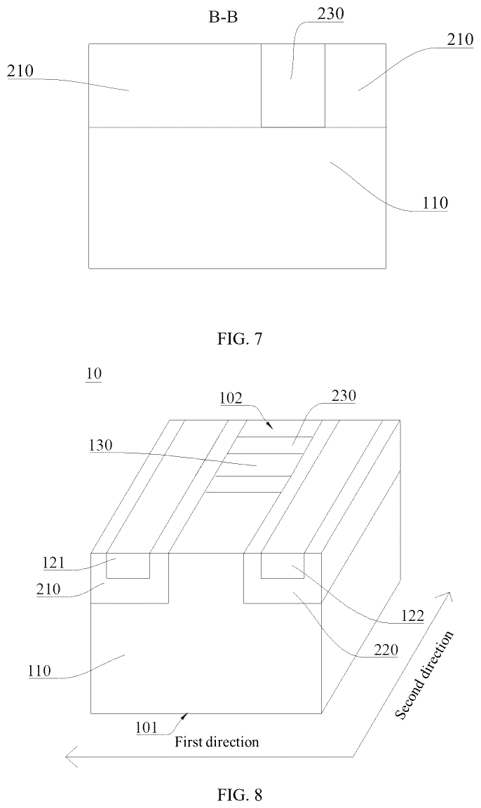

Specifically, the epitaxial layer 110 includes a first surface 101 and a second surface 102 opposite to each other. The first body area 210 and the second body area 220 are disposed in the epitaxial layer 110, and are disposed on a side of the epitaxial layer 110 proximate to the second surface 102. The first body area 210 and the second body area 220 are opposite in a first direction and are arranged at intervals, and extend along a second direction crossing the first direction. As shown in FIG. 3, the reinforcing layer 230 is disposed between the first body area 210 and the second body area 220, and the reinforcing layer 230 extends along the first direction. As shown in FIGS. 4-7, the reinforcing layer 230 is in contact with the first body area 210, the second body area 220 and the epitaxial layer 110. Specifically, the first direction and the second direction are directions shown as FIG. 2. The first source area 121 and the second source area 122 are embedded in the first body area 210 and the second body area 220, respectively. The first body area 210 blocks the first source area 121 and the epitaxial layer 110, and the second body area 220 blocks the second source area 122 and the epitaxial layer 110. The first source area 121 is disposed to correspond to the first body area 210 in position, and the second source area 122 is disposed to correspond to the first second area 220 in position.

As shown in FIG. 2, the oxide layer 400 is disposed on the second surface 102 and extends along the second direction, and the oxide layer 400 is connected to the epitaxial layer 110, the first body area 210, the second body area 220, the first source area 121, the second source area 122 and the reinforcing layer 230. As an insulator, the oxide layer 400 can be silicon dioxide. As shown in FIGS. 1 and 2, polysilicon 600 is disposed above the oxide layer 400. Doping concentrations of the first body area 210, the second body area 220 and the reinforcing layer 230 are the same. A doping type of each of the first body area 210, the second body area 220 and the reinforcing layer 230 is a first doping type, and a doping type of each of the first source area 121, the second source area 122 and the epitaxial layer 110 is a second doping type. Specifically, the first doping type is a P-type, and the second doping type is a N-type.

In the silicon carbide MOSFET structure 10 provided by the embodiments of the disclosure, a partially conductive area of the epitaxial layer 110 is reinforced through setting the reinforcing layer 230 shown as FIG. 3, while a channel width is not affected, so as to improve reliability of the silicon carbide MOSFET structure 10, and improve stability of the silicon carbide MOSFET structure 10.

Specifically, the channel width is a width of a conductive channel located between a source electrode and a drain electrode in the silicon carbide MOSFET structure. In the embodiments of the disclosure, when the channel width remains unchanged, a partially area of the epitaxial layer 110 between the first body area 210 and the second body area 220 is reinforced through setting the reinforcing layer 230, thereby increasing electric field distribution, and making the electric field more even. Meanwhile, the electric field intensity proximate to a surface of the channel is reduced, so as to decrease an effect of uneven electric field intensity on the silicon carbide MOSFET structure 10. Setting of the reinforcing layer 230 makes the electric field distribution more even, reduces a peak value of the electric field proximate to the surface of the channel, and decrease a risk of breakdown of the oxide layer 400, so as to improve the reliability of the silicon carbide MOSFET structure 10. Moreover, the doping concentrations and the doping types of the first body area 210, the second body area 220 and the reinforcing layer 230 are the same, which helps to ensure consistency and stability of the silicon carbide MOSFET structure 10. Through optimizing the electric field distribution, the embodiments of the disclosure decrease the peak value of the electric field, reduce the effect caused by the uneven electric field intensity on the silicon carbide MOSFET structure 10, and improve the reliability of the silicon carbide MOSFET structure 10.

In an embodiment, as shown in FIG. 8, a number of the reinforcing layers 230 is multiple, and the multiple reinforcing layers 230 are arranged at intervals along the second direction. Through setting the multiple reinforcing layers 230, the electric field intensity can be distributed to a larger area, and each reinforcing layer 230 can share load of the electric field, so as to reduce the electric field intensity of a single reinforcing layer 230, and reduce concentration of the electric field, so that the electric field can be distributed between different layers and transferred between them. In this way, the intensity of a local electric field is reduced, the risk of damage to the silicon carbide MOSFET structure 10 caused by the electric field is reduced, and the electric field intensity proximate to the surface of the channel is reduced, thereby reducing the effect of the uneven electric field intensity on the silicon carbide MOSFET structure 10, making the electric field distribution more even, reducing the peak value of the electric field proximate to the surface of the channel, reducing the risk of breakdown of the oxide layer 400, and further improving the reliability of the silicon carbide MOSFET structure 10.

Specifically, an interval range between two adjacent reinforcing layers is 0.1-10 μm. Through setting a proper interval, electric field distribution between the reinforcing layers 230 can be adjusted. A small interval can make the electric field more concentrated, so that an efficiency of current transmission is improved. A large interval can make the electric field distribution more even, so that the effect of the electric field on the structure is alleviated. Through adjusting the interval, the electric field distribution can be optimized, and performances and the reliability of the silicon carbide MOSFET structure 10 are improved. In addition, a crosstalk effect may be caused by mutual interference of electric fields between adjacent devices in a high-density integrated circuit. Through setting the proper interval, an electric field coupling between adjacent reinforcing layers 230 can be reduced, so as to decrease occurrence of the crosstalk effect, which helps to improve the stability and the reliability of the device. When the interval between the adjacent reinforcing layers 230 is extremely small, it may cause structural short circuits, and the proper interval can effectively prevent occurrence of the short circuit, and ensure a normal work of the device. In summary, through setting the interval between the adjacent two reinforcing layers 230 within the range of 0.1-10 μm, the electrical field distribution can be optimized, the crosstalk effect can be reduced, and the structural short circuit can be prevented, which helps to improve the performances, the reliability and the stability of the silicon carbide MOSFET structure.

As shown in FIGS. 8-10, the silicon carbide MOSFET structure 10 further includes a buffer layer 130. The buffer layer 130 is disposed in the epitaxial layer 110, and is disposed between the two adjacent reinforcing layers 230. A doping type of the buffer layer 130 is the second doping type, and a doping concentration of the buffer layer 130 is different from a doping concentration of the epitaxial layer 110. Through setting the buffer layer 130, a different in the electric field intensity between the epitaxial layer 110 and the reinforcing layer 230 is reduced. Due to the different doping concentrations of the buffer layer 130 and the epitaxial layer 110, an electric potential distribution between the epitaxial layer 110 and the reinforcing layer 230 can be changed, and the electric field distribution is homogenized. Specifically, due to the existence of the buffer layer 130, when there is an electric field difference between the epitaxial layer 110 and the reinforcing layer 230, the electric field is distributed between the buffer layer 130 and the reinforcing layer 230, rather than concentrated at an interface between the epitaxial layer 110 and the reinforcing layer 230. Therefore, an electric field gradient between the epitaxial layer 110 and the reinforcing layer 230 is reduced, the electric field intensity is decreased, and the electric field distribution between the epitaxial layer 110 and the reinforcing layer 230 are optimized, thereby improving the stability of the silicon carbide MOSFET structure 10.

In an embodiment, the doping concentration of the buffer layer 130 is lower than a doping concentration of each of the first source area 121 and the second source area 122, and the doping concentration of the epitaxial layer 110 is lower than the doping concentration of the buffer layer 130. Since the doping concentration of the buffer layer 130 is lower than the doping concentration of each of the first source area 121 and the second source area 122, the buffer layer 130 plays a buffer role in the electric field distribution. When external voltage is applied to this structure, a gradient electric potential peak is formed between the epitaxial layer 110 and the buffer layer 130, and the electric field is gradually distributed in the buffer layer 130, thereby blocking the effect of the electric field on the first source area 121 and the second source area 122. Therefore, the effect of the electric field intensity on the source areas is decreased, and the reliability of the silicon carbide MOSFET structure 10 is improved. Secondly, since the doping concentration of the epitaxial layer 110 is lower than the doping concentration of the buffer layer 130, the epitaxial layer 110 has a high conductivity relative to the buffer layer 130. When the external voltage is applied to the structure, charge can flow more smoothly through the epitaxial layer 110 due to the high conductivity of the epitaxial layer 110, so as to reduce conduction impedance, decrease heat generated during forward conduction operation of the silicon carbide MOSFET structure 10 as a power device, and make the silicon carbide MOSFET structure 10 more stable. Meanwhile, the low doping concentration of the epitaxial layer 110 reduces an effect of an impurity concentration on conductive performance. Therefore, such settings not only reduce the effect of resistance, but also improve the reliability of the silicon carbide MOSFET structure 10. In summary, through setting the doping concentration of the buffer layer 130 lower than the doping concentrations of the first source area 121 and the second source area 122, and the doping concentration of the epitaxial layer 110 lower than the doping concentration of the buffer layer 130, the difference in the electric field intensity is decreased, so that the effect of the electric field on the source areas is reduced, the effect of the resistance is reduced, and the reliability and the stability of the silicon carbide MOSFET structure 10 are improved.

Specifically, a number of impurity atoms per cubic centimeter of the first body area 210 and the second body area 220 is 10¹⁷, and the doping concentration of the reinforcing layer 230 is the same as the doping concentration of each of the first body area 210 and the second body area 220. A number of impurity atoms per cubic centimeter in the buffer layer 130 is in a range of 10¹⁷-10¹⁸. A thickness range of the buffer layer 130 in a direction from the second surface 102 to the first surface 101 is 0.1-10 μm. As shown in FIGS. 8-10, an interval range between the two adjacent reinforcing layers 230 is 0.1-10 μm.

A thickness of the buffer layer 130 in a direction from the first surface 101 to the second surface 102 is the same as a thickness of the reinforcing layer 230 in the direction from the first surface 101 to the second surface 102.

Specifically, by per cubic centimeter, the doping concentration of the epitaxial layer 110 is on the order of 13 to 15 powers of 10, the doping concentration of the buffer layer 130 is on the order of 17 to 19 powers of 10, and the doping concentrations of the first source area 121 and the second source area 122 are on the order of 19 power of 10. Through setting the buffer layer 130 with high doping concentration, the conduction impedance of the silicon carbide MOSFET structure 10 is decreased, thereby reducing the heat generated during forward conduction operation of the silicon carbide MOSFET structure 10 as the power device, and making the silicon carbide MOSFET structure 10 more stable.

The embodiments of the disclosure provide a preparation method of the silicon carbide MOSFET structure 10, and the preparation method includes the following steps S1-S4.

In step S1, as shown in FIG. 1, an epitaxial layer 110 is generated through ion implantation, and the epitaxial layer 110 includes a first surface 101 and the second surface 102.

In step S2, a first body area 210, a second body area 220 and a reinforcing layer 230 are generated on the epitaxial layer 110 through the ion implantation. The first body area 210 and the second body area 220 are disposed on a side of the epitaxial layer 110 proximate to the second surface 102, the first body area 210 and the second body area 220 are opposite in a first direction and are arranged at intervals, and the first body area 210 and the second body area 220 extend along a second direction crossing the first direction. The reinforcing layer 230 is disposed between the first body area 210 and the second body area 220, and extends along the first direction, and the reinforcing layer 230 is in contact with the first body area 210, the second body area 220 and the epitaxial layer 110.

In step S3, a first source area 121 is formed on the first body area 210, and a second source area 122 is formed on the second body area 220. The first source area 121 is disposed on a side of the first body area 210 proximate to the second surface 102, the second source area 122 is disposed on a side of the second body area 220 proximate to the second surface 102, and the first source area 121 and the second source area 122 extend along the second direction.

In step S4, an oxide layer 400 shown as FIG. 1 is formed on the second surface 102 through mask and etching methods. The oxide layer 400 extends along the second direction, and the oxide layer 400 is connected to the epitaxial layer 110, the first body area 210, the second body area 220, the first source area 121, the second source area 122 and the reinforcing layer 230. As an insulator, the oxide layer 400 can be silicon dioxide.

Specifically, the reinforcing layer is multiple in number, and a step of generating the first body area 210, the second body area 220 and the reinforcing layer 230 on the epitaxial layer 110 includes: forming the multiple reinforcing layers 230 between the first body area 210 and the second body area 220. The multiple reinforcing layers 230 are arranged at intervals along the second direction. The first doping type is a P-type, and the second doping type is an N-type.

At least the silicon carbide MOSFET structure 10 shown as FIG. 1 can be obtained through implementing the preparation method of the silicon carbide MOSFET structure 10 provided by the embodiments of the disclosure. Through changing mask patterns in corresponding steps, any one of the silicon carbide MOSFET structures 10 shown as FIGS. 1-10 can be obtained through the preparation method of the silicon carbide MOSFET structure 10 provided by the embodiments of the disclosure. Technical effects of the obtained silicon carbide MOSFET structures 10 can be found in the embodiments of the disclosure.

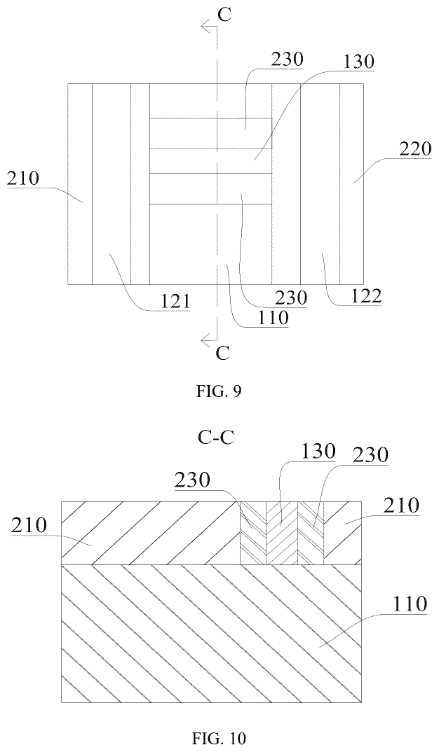

In an embodiment, the preparation method further includes step 5. In the step 5, a buffer layer 130 is formed in the epitaxial layer 110. The buffer layer 130 extends along a direction from the first surface 101 to the second surface 102, and is disposed between two adjacent reinforcing layers 230. A doping concentration of the buffer layer 130 is different from a doping concentration of the epitaxial layer 110, and a doping type of the buffer layer 130 is the second doping type. For example, the buffer layer 130 shown as FIG. 9 is generated through mask and ion implantation.

Furthermore, it can be understood that the aforementioned embodiments are merely illustrative examples of the disclosure. On the premise that the technical features do not conflict, are fixed and do not contradict, and do not violate a purpose of the disclosure, the technical solutions of each embodiment can be freely combined and used in combination.

Finally, it should be noted that the above embodiments are merely used to illustrate the technical solution of the disclosure, and not to limit it; Although detailed descriptions of the disclosure have been provided by referring to the aforementioned embodiments, those skilled in the art should understand that they can still modify the technical solutions recorded in the aforementioned embodiments or equivalently replace some of the technical features thereof, and these modifications or replacements do not make essence of the corresponding technical solutions deviate from a spirit and scope of the technical solutions of the various embodiments of the disclosure.

What is claimed is:

1. A preparation method of a silicon carbide metal-oxide-semiconductor field effect transistor (MOSFET) structure, comprising:
generating an epitaxial layer; wherein the epitaxial layer comprises a first surface and a second surface;
generating a first body area, a second body area and a reinforcing layer on the epitaxial layer; wherein the first body area and the second body area are disposed on a side of the epitaxial layer proximate to the second surface, the first body area and the second body area are opposite in a first direction and are arranged at intervals, and the first body area and the second body area extend along a second direction crossing the first direction; and the reinforcing layer is disposed between the first body area and the second body area, and extends along the first direction, and the reinforcing layer is in contact with the first body area, the second body area and the epitaxial layer;
forming a first source area on the first body area, and forming a second source area on the second body area; wherein the first source area is disposed on a side of the first body area proximate to the second surface, the second source area is disposed on a side of the second body area proximate to the second surface, and the first source area and the second source area extend along the second direction; and
forming an oxide layer on the second surface; wherein the oxide layer extends along the second direction, and the oxide layer is connected to the epitaxial layer, the first body area, the second body area, the first source area, the second source area and the reinforcing layer;
wherein doping concentrations of the first body area, the second body area and the reinforcing layer are the same; and a doping type of each of the first body area, the second body area and the reinforcing layer is a first doping type, and a doping type of each of the first source area, the second source area and the epitaxial layer is a second doping type.

2. The preparation method as claimed in claim 1, wherein the reinforcing layer is multiple in number, and the generating a first body area, a second body area and a reinforcing layer on the epitaxial layer, comprises:
forming the multiple reinforcing layers between the first body area and the second body area; wherein the multiple reinforcing layers are arranged in the second direction and arranged at intervals.

3. The preparation method as claimed in claim 2, wherein the preparation method further comprises:
generating a buffer layer in the epitaxial layer; wherein the buffer layer is disposed between two adjacent reinforcing layers of the multiple reinforcing layers, a doping type of the buffer layer is the second doping type, and a doping concentration of the buffer layer is different from a doping concentration of the epitaxial layer.

4. The preparation method as claimed in claim 3, wherein the doping concentration of the buffer layer is lower than a doping concentration of each of the first source area and the second source area, and the doping concentration of the epitaxial layer is lower than the doping concentration of the buffer layer.

5. The preparation method as claimed in claim 2, wherein an interval range between two adjacent reinforcing layers of the multiple reinforcing layers is 0.1-10 microns (μm).

6. The preparation method as claimed in claim 3, wherein a number of impurity atoms per cubic centimeter in the buffer layer ranges from 10¹⁷-10¹⁸.

7. The preparation method as claimed in claim 3, wherein a thickness of the buffer layer in a direction from the first surface to the second surface is the same as a thickness of the reinforcing layer in the direction from the first surface to the second surface.

8. The preparation method as claimed in claim 3, wherein a thickness range of the buffer layer in a direction from the first surface to the second surface is 0.1-10 μm.

9. A silicon carbide MOSFET structure, wherein the silicon carbide MOSFET structure is prepared by using the preparation method as claimed in claim 1.

10. A silicon carbide MOSFET structure, comprising:
an epitaxial layer, comprising a first surface and a second surface opposite to each other;
a first body area and a second body area, disposed in the epitaxial layer; wherein the first body area and the second body area are disposed on a side of the epitaxial layer proximate to the second surface, and the first body area and the second body area are opposite in a first direction and are arranged at intervals, and the first body area and the second body area extend along a second direction crossing the first direction;
a reinforcing layer, disposed between the first body area and the second body area; wherein the reinforcing layer extends along the first direction, and the reinforcing layer is in contact with the first body area, the second body area and the epitaxial layer;
a first source area and a second source area; wherein the first source area is embedded in the first body area, and the second source area is embedded in the second body area; the first source area is located at a side of the first body area proximate to the second surface, and the second source area is located at a side of the second body area proximate to the second surface; and the first source area and the second source area extend along the second direction; and
an oxide layer, disposed on the second surface and extending along the second direction; wherein the oxide layer is connected to the epitaxial layer, the first body area, the second body area, the first source area, the second source area and the reinforcing layer;
wherein doping concentrations of the first body area, the second body area and the reinforcing layer are the same; and a doping type of each of the first body area, the second body area and the reinforcing layer is a P-type, and a doping type of each of the first source area, the second source area and the epitaxial layer is an N-type.
